(19) United States
(12) Patent Application Publication
(10) Pub. No.: US 2026/0107552 A1
(43) Pub. Date: Apr. 16, 2026

(54) THROUGH-HOLE Z-AXIS POWER DELIVERY MODULE

(71) Applicant: Monolithic Power Systems, Inc., San Jose, CA (US)

(72) Inventors: Eric NGUYEN, San Jose, CA (US); Ting GE, San Jose, CA (US)

(21) Appl. No.: 19/227,051

(22) Filed: Jun. 3, 2025

Related U.S. Application Data
(60) Provisional application No. 63/707,902, filed on Oct. 16, 2024.

(51) Int. Cl. H10D 80/20; H01L 23/367; H01L 23/498; H01L 25/18; H10D 80/30

(52) U.S. Cl. CPC H10D 80/251; H10D 80/215; H10D 80/30; H10W 40/226; H10W 90/00; H10W 90/401; H10W 90/701

(57) ABSTRACT

An electronics assembly includes a motherboard, a processor, and a z-axis power delivery (ZPD) module. The processor is mounted on the motherboard. The ZPD module is electrically connected to a substrate of the processor through an opening that goes all the way through the motherboard. The processor may be a central processing unit (CPU), a graphics processing unit (GPU), or a system-on-a-chip (SOC), for example.

### CROSS-REFERENCE TO RELATED APPLICATION

This application claims the benefit of U.S. Provisional Application No. 63/707,902, filed on Oct. 16, 2024, which is incorporated herein by reference in its entirety.

### TECHNICAL FIELD

The present disclosure relates to power electronics.

### BACKGROUND

A z-axis power delivery (ZPD) module is a power supply component that delivers electrical power vertically along the z-axis of a three-dimensional structure. In the context of powering high-performance processors, such as a central processing unit (CPU), graphics processing unit (GPU), or system-on-a-chip (SoC) mounted on a motherboard, the ZPD module supplies power vertically from a location beneath or near the socket of the processor. This approach bypasses traditional horizontal power delivery routes through the motherboard's power planes. Horizontal routing often introduces inefficiencies, particularly due to longer distances and resistive losses, which become more pronounced as power demands increase in modern, high-performance processors.

FIG. 1 shows a schematic representation of a conventional electronics assembly with a ZPD module 100. The ZPD module 100 is disposed on the backside of a motherboard 102. A substrate 101 of a processor is disposed on the topside of the motherboard 102. The ZPD module 100 delivers power to the processor by way of power planes of the motherboard 102. A cold plate 103 is attached to the ZPD module 100 and power modules 104, which are disposed on the backside of the motherboard 102.

### BRIEF SUMMARY

In one embodiment, an electronics assembly comprises a motherboard, a processor, and a z-axis power delivery (ZPD) module. The motherboard defines a hole that extends entirely through the motherboard. The processor has a substrate that is mounted on the motherboard. The ZPD module is attached to the substrate of the processor through the hole in the motherboard.

These and other features of the present disclosure will be readily apparent to persons of ordinary skill in the art upon reading the entirety of this disclosure, including the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The figures are not drawn to scale.

FIG. 1 shows a schematic representation of conventional electronics assembly with a ZPD module.

FIG. 2 shows a schematic representation of an electronics assembly, in accordance with an embodiment of the present invention.

FIG. 3 shows a side view of a through-hole ZPD module, in accordance with an embodiment of the present invention.

FIG. 4 shows a planar view of a capacitor layer of a through-hole ZPD module, in accordance with an embodiment of the present invention.

FIG. 5 shows a planar view of a module layer of a through-hole ZPD module, in accordance with an embodiment of the present invention.

FIG. 6 shows an exploded view of an electronics assembly, in accordance with an embodiment of the present invention.

FIG. 7 shows a perspective view of an electronics assembly, in accordance with an embodiment of the present invention.

FIG. 8 shows a side view of an electronics assembly, in accordance with an embodiment of the present invention.

FIGS. 9-13 are side views that illustrate an assembly process of an electronics assembly, in accordance with an embodiment of the present invention.

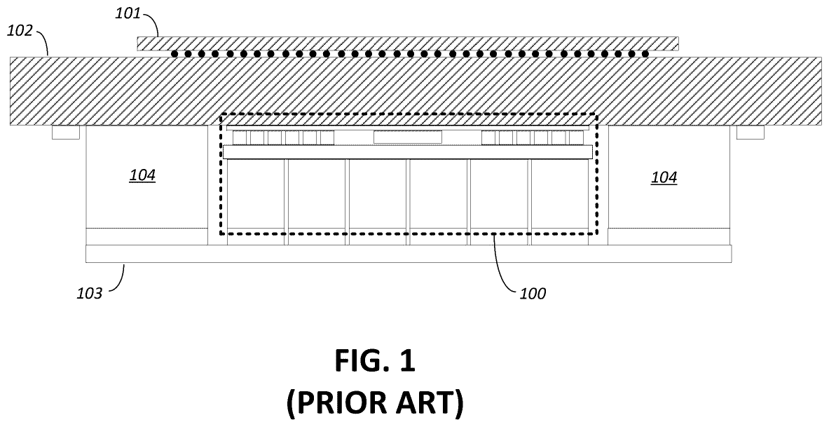

### DETAILED DESCRIPTION

In the present disclosure, numerous specific details are provided, such as examples of circuits, components, structures, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

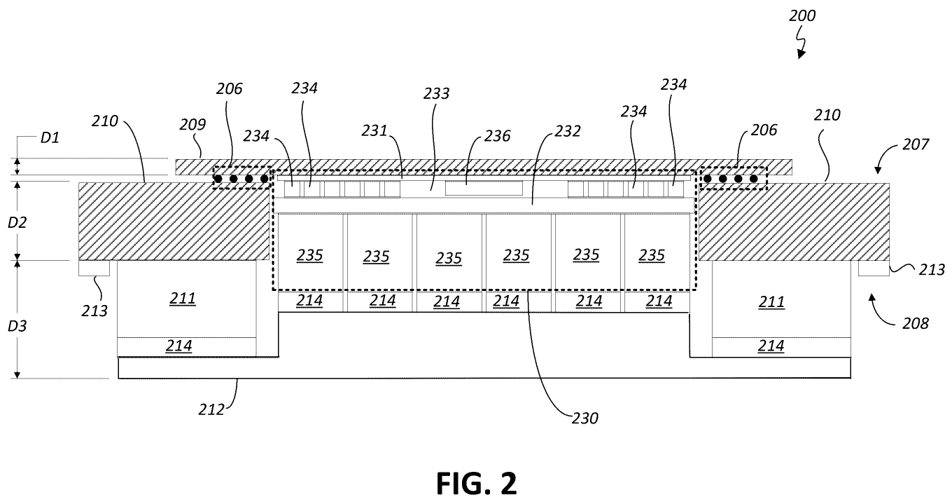

FIG. 2 shows a schematic representation of an electronics assembly 200, in accordance with an embodiment of the present invention. The electronics assembly 200 may include a motherboard 210, a through-hole Z-axis power delivery (ZPD) module 230, and a processor substrate 209.

The motherboard 210, which may be a printed circuit board (PCB), includes a topside 207 and a backside 208. One or more power modules 211 may be mounted on the backside 208 of the motherboard 210. The power modules 211 may be configured to supply power to a processor or other components on the motherboard 210. The inclusion of the power modules 211 are optional, depending on specific power delivery requirements. One or more output capacitors 213 may also be mounted on the backside 208 of the motherboard 210.

The processor substrate 209 may house a central processing unit (CPU), graphics processing unit (GPU), system-on-a-chip (SoC), or another high-performance processor. The processor substrate 209 may comprise a material commonly used in semiconductor packaging.

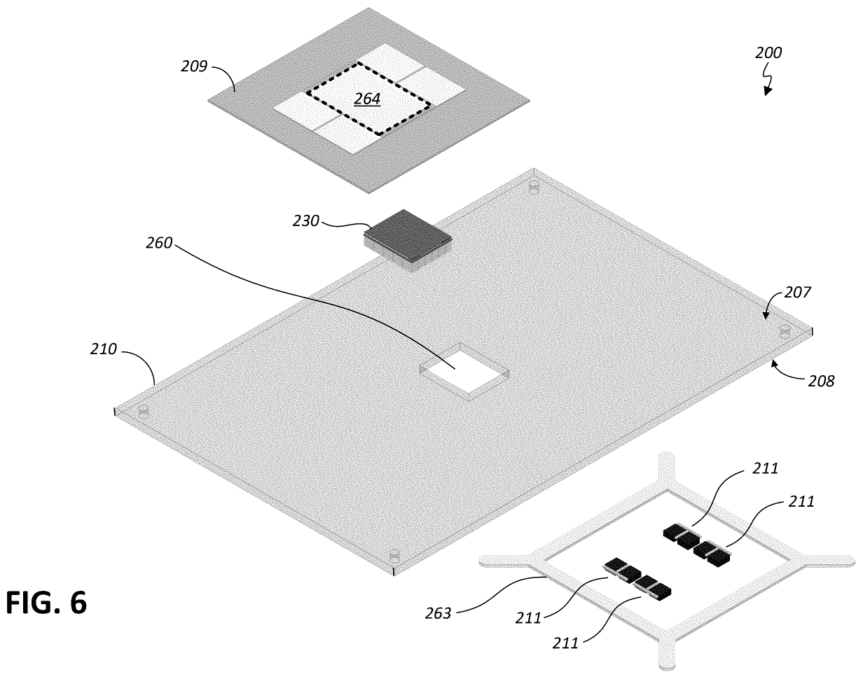

The through-hole ZPD module 230 is configured to supply power to the processor housed within the processor substrate 209. As the name suggests, the through-hole ZPD module 230 is oriented along a vertical (Z-axis) direction relative to the plane of the motherboard 210, and it extends through a hole (see FIG. 6, hole 260) that goes all the way through the motherboard 210. In one embodiment, the through-hole ZPD module 230 includes a first module substrate 231 and a second module substrate 232. Each of the first and second module substrates 231, 232 may comprise a PCB or another type of substrate. A capacitor layer 233 may be positioned between the first module substrate 231 and the second module substrate 232. Disposed in the capacitor layer 233 are a controller 236 and one or more capacitors 234. The capacitors 234 may include input capacitors and/or output capacitors. The controller 236 may be a pulse width modulation (PWM) controller or another type of control circuit configured to regulate the operation of a plurality of sub-modules 235. In one embodiment, the controller 236 and the capacitors 234 are mounted on the first module substrate 231.

In some embodiments, the first module substrate 231 may be omitted. In such cases, the capacitors 234 may be mounted directly to corresponding contact points on the processor substrate 209, and the controller 236 may be mounted on the second module substrate 232.

The through-hole ZPD module 230 further includes a module layer in which an array of sub-modules 235 is disposed. Each sub-module 235 may include a driver MOSFET (DrMOS) module, a regulator block, an output inductor block, a circuit phase, or another power conversion element. For example, each sub-module 235 may comprise a pair of synchronous transistors that are driven by PWM by the controller 236 to generate a regulated output voltage VOUT. In one embodiment, the sub-modules 235 are mounted on the second module substrate 232. A cold plate 212 is thermally coupled to both the sub-modules 235 and the power modules 211 via a thermal interface material 214. The cold plate 212 has a non-planar profile, with a thicker middle region to accommodate the sunken positioning of the sub-modules 235 relative to the power modules 211.

In one embodiment, a thickness D1 of the processor substrate 209 is approximately 1.00 mm, a thickness D2 of the motherboard 210 is approximately 5.00 mm, and a height D3 of the stack comprising the power modules 211, thermal interface material 214, and cold plate 212 is approximately 7.60 mm.

In the example shown in FIG. 2, the through-hole ZPD module 230 is electrically connected to the processor substrate 209 through the hole (see FIG. 6, hole 260) that extends through the full thickness of the motherboard 210. Current supplied by the through-hole ZPD module 230 bypasses the ball grid array (BGA) 206, which electrically connects contact points (e.g., pads) on the motherboard 210 to those on the processor substrate 209. By bypassing the BGA 206 and the internal layers of the motherboard 210, the impedance of the power delivery path is significantly reduced, thereby improving power efficiency and transient response. For example, the connection structure of the through-hole ZPD module 230 may include a land grid array (LGA), which allows for higher current density than the BGA 206.

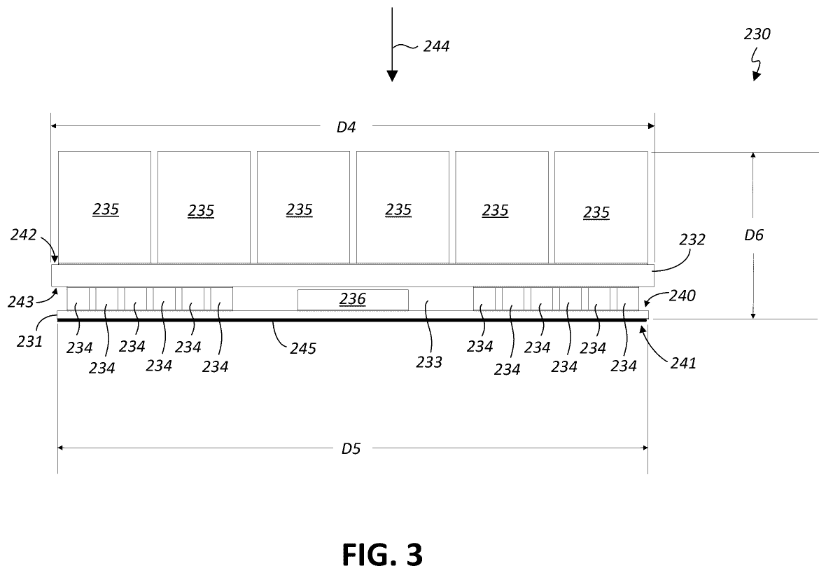

FIG. 3 shows a side view of the through-hole ZPD module 230, in accordance with an embodiment of the present invention. The first module substrate 231 includes a first side 240, on which the capacitors 234 and the controller 236 are mounted, and a second side 241 that faces the processor substrate 209 (shown in FIG. 2). In some embodiments, the controller 236 may instead be mounted on the second module substrate 232. A connection structure 245, which in one embodiment is a land grid array (LGA), is formed on the second side 241 and is configured to electrically connect to contact points on the processor substrate 209.

The second module substrate 232 includes a first side 242, on which the sub-modules 235 are mounted, and a second side 243 that faces the capacitors 234. Empty spaces between the first module substrate 231 and the second module substrate 232 may be filled with a molding material to enhance mechanical robustness.

In one embodiment, the second module substrate 232 has a width D4 of approximately 27.30 mm, the first module substrate 231 has a width D5 of approximately 26.80 mm, and the total height D6 from the top of the sub-modules 235 to the second side 241 of the first module substrate 231 is approximately 7.60 mm. A reference arrow 244, which points toward the sub-modules 235, is used for orientation in subsequent figures.

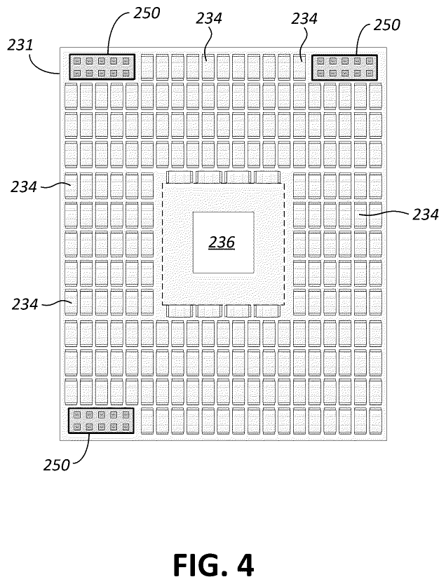

FIG. 4 shows a planar view of the capacitor layer 233, in accordance with an embodiment of the present invention. FIG. 4 depicts the capacitor layer 233 as seen in the direction of reference arrow 244 in FIG. 3, with the module layer omitted for clarity. Signal connectors 250 provide electrical connections between the capacitor layer 233 and the sub-modules 235. The signal connectors 250 may be implemented using PCB connectors, copper blocks, or vias. Similarly, power conversion connections, such as input voltage (VIN), output voltage (VOUT), and ground, between the capacitor layer 233 and the sub-modules 235 may be implemented using PCB connectors, copper pillars, vias, or capacitor terminals. In general, electrical connections between the capacitor layer 233 and the sub-modules 235 may be implemented in a variety of ways without limiting the scope of the present invention.

The capacitor layer 233 may be implemented using a variety of structural configurations. In some embodiments, the capacitor layer comprises an open frame that mechanically supports discrete capacitors between the substrates without encapsulation. In other embodiments, the capacitor layer 233 is formed using a molding compound that encapsulates the capacitors 234 for structural and environmental protection. In yet other embodiments, the capacitors 234 are embedded within one or more internal layers of the first module substrate 231.

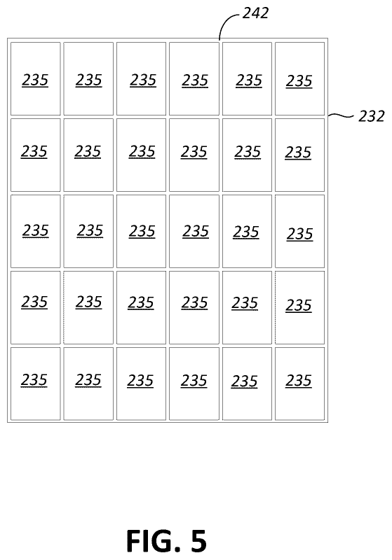

FIG. 5 shows a planar view of the module layer containing the sub-modules 235, in accordance with an embodiment of the present invention. FIG. 5 depicts the module layer as seen in the direction of reference arrow 244 in FIG. 3. A plurality of sub-modules 235 may be mounted on the first side 242 of the second module substrate 232. In the example of FIG. 5, each sub-module 235 comprises a DrMOS module that provides two power phases. For an input voltage in the range of 3 V to 8 V, each sub-module 235 may be configured to deliver a Thermal Design Current (TDC) of approximately 90 A. With physical dimensions of approximately 27.3 mm×32.8 mm×7.6 mm, a total of 30 sub-modules 235 may collectively provide a TDC of approximately 2700 A. The through-hole ZPD module 230 is particularly well-suited for high-current applications of this type, as it bypasses the motherboard and enables a higher current density electrical connection to the processor substrate 209.

FIG. 6 shows an exploded view of the electronics assembly 200, in accordance with an embodiment of the present invention. The cold plate 212 is not shown in FIG. 6. In the example of FIG. 6, a stiffener 263 and the power modules 211 are attached to the backside 208 of the motherboard 210. The stiffener 263 may be made of aluminum or another suitable material. The hole 260 extends completely through the thickness of the motherboard 210. The through-hole ZPD module 230 is positioned within the hole 260 and is configured to electrically connect to a processor 264 that is housed within the processor substrate 209.

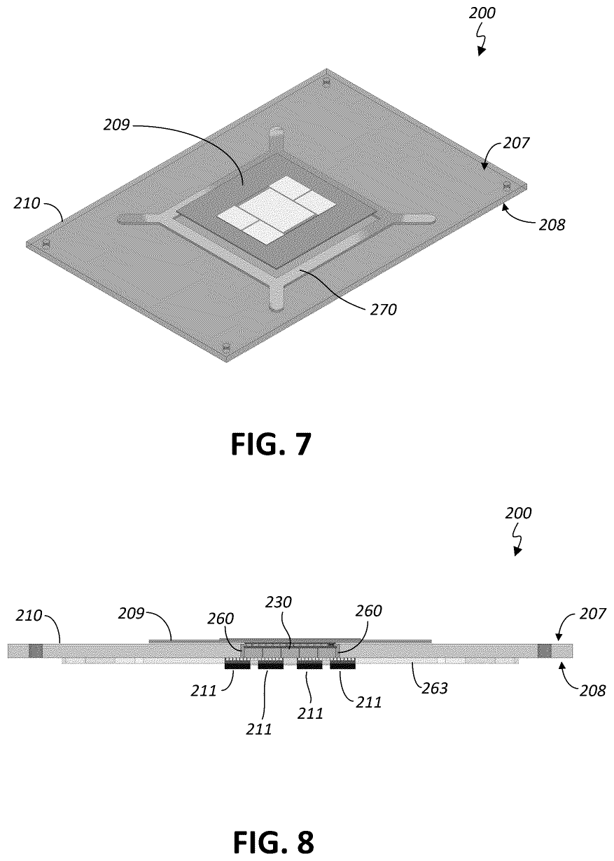

FIG. 7 shows a perspective view of the electronics assembly 200, in accordance with an embodiment of the present invention. In the example of FIG. 7, a stiffener 270 is attached to the topside 207 of the motherboard 210 and surrounds the processor substrate 209 to provide structural reinforcement.

FIG. 8 shows a side view of the electronics assembly 200, in accordance with an embodiment of the present invention. FIG. 8 illustrates the stiffener 263 and the power modules 211 mounted on the backside 208 of the motherboard 210. The processor substrate 209 is mounted on the topside 207 of the motherboard 210. The through-hole ZPD module 230 is electrically connected to the processor substrate 209 through the hole 260 in the motherboard 210.

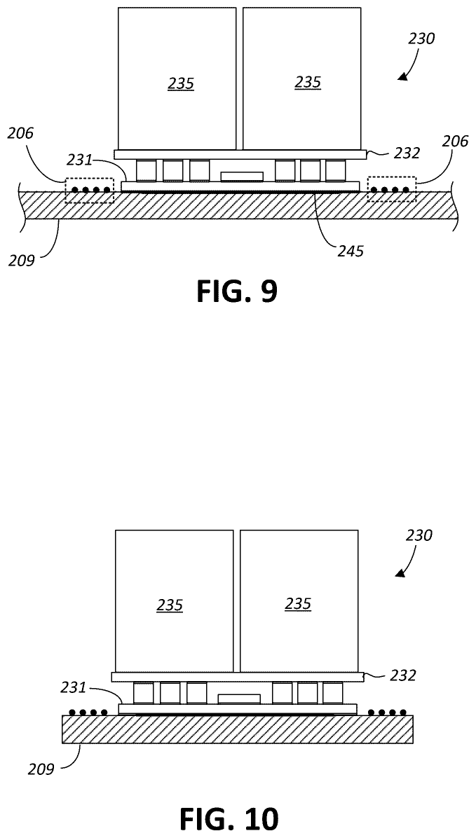

FIGS. 9-13 are side views that illustrate an assembly process of the electronics assembly 200, in accordance with an embodiment of the present invention. The components labeled in FIGS. 9-13 correspond to those described in previous figures. These components are identified for reference and are not necessarily described again in each of the following figures.

Referring to FIG. 9, in a first step, the through-hole ZPD module 230 is soldered to the processor substrate 209. In one embodiment, the connection structure 245 on the first module substrate 231 is soldered to corresponding connection points (e.g., pads, terminals, or pins) on the processor substrate 209 using surface mount technology (SMT). Ball grid arrays (BGAs) 206 are also attached to the processor substrate 209.

Referring to FIG. 10, in a second step, singulation is performed on the intermediate structure shown in FIG. 9 to separate the processor substrate 209 from the surrounding processor substrate material. This step results in a single, integrated module comprising the through-hole ZPD module 230 and the processor substrate 209.

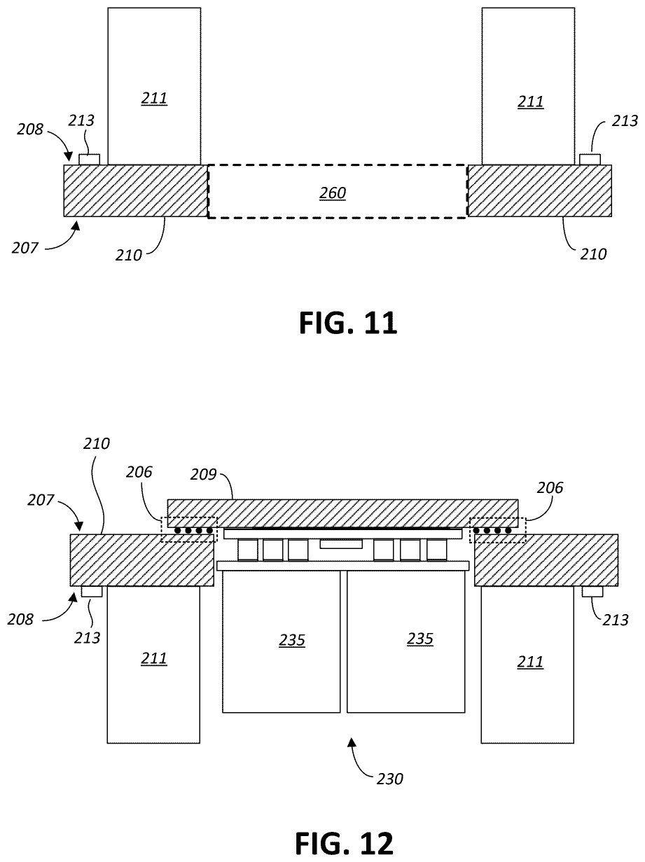

Referring to FIG. 11, in a third step, the power modules 211 and the capacitors 213 are soldered to the backside 208 of the motherboard 210, for example using SMT. The hole 260, which extends completely through the motherboard 210, is visible in this view.

Referring to FIG. 12, in a fourth step, the structure formed in FIG. 10, i.e., the through-hole ZPD module 230 attached to the processor substrate 209, is inserted through the hole 260 in the motherboard 210 from the topside 207. The processor substrate 209 is then soldered to the topside 207 of the motherboard 210. In one embodiment, the BGAs 206 are soldered to corresponding connection points (e.g., pads, terminals, or pins) on the motherboard 210 using SMT.

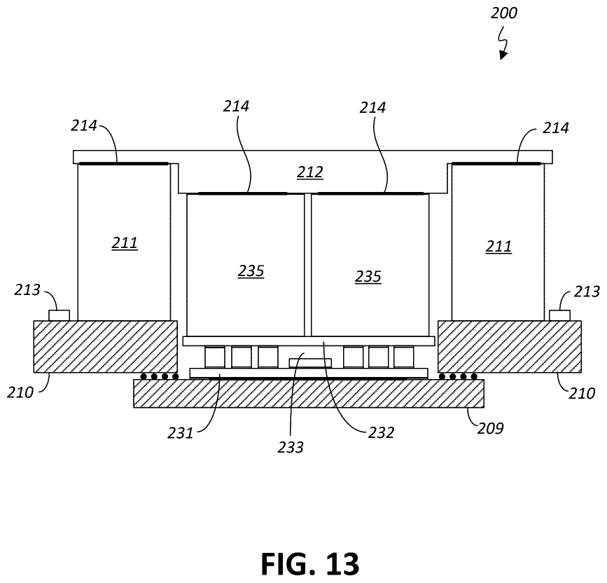

Referring to FIG. 13, in a fifth step, the cold plate 212 is attached to the power modules 211 and to the sub-modules 235 of the through-hole ZPD module 230. The cold plate 212 may be thermally coupled to the power modules 211 and the sub-modules 235 by way of the thermal interface material 214.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. An electronics assembly, comprising:
a motherboard having a first side and a second side, the motherboard defining a hole that extends through the motherboard;
a processor having a substrate, the substrate mounted on the first side of the motherboard; and
a z-axis power delivery (ZPD) that is electrically connected to deliver power to the processor, wherein the ZPD module is attached to the substrate of the processor through the hole in the motherboard.

2. The electronics assembly of claim 1, wherein the processor comprises a central processing unit (CPU), a graphics processing unit (GPU), or a system-on-a-chip (SoC).

3. The electronics assembly of claim 1, wherein the processor is electrically connected to corresponding connection points on the motherboard by a first connection structure, the ZPD module is electrically connected to corresponding connection points on the substrate of the processor by a second connection structure, and the first and second connection structures are different types.

4. The electronics assembly of claim 3, wherein the first connection structure comprises a ball grid array (BGA), and the second connection structure comprises a land grid array (LGA).

5. The electronics assembly of claim 1, wherein the ZPD module comprises a first substrate and a second substrate, and a plurality of capacitors is disposed between the first and second substrates.

6. The electronics assembly of claim 5, wherein a connection structure that electrically connects the ZPD module to the processor is disposed on the first substrate.

7. The electronics assembly of claim 6, further comprising a plurality of sub-modules disposed on the second substrate, each of the sub-modules comprising a pair of synchronous transistors driven by a controller disposed between the first and second substrates.

8. An electronics assembly, comprising:
a motherboard;
a processor substrate that houses a processor, the processor substrate mounted on the motherboard; and
a z-axis power delivery (ZPD) module that is electrically connected to the processor, wherein the ZPD module is disposed through a hole that extends all the way through the motherboard.

9. The electronics assembly of claim 8, wherein the ZPD module comprises a plurality of capacitors, a plurality of sub-modules, and a controller configured to regulate operation of the plurality of sub-modules.

10. The electronics assembly of claim 9, wherein the controller comprises a pulse width modulation (PWM) controller, and each of the plurality of sub-modules comprises a pair of synchronous transistors driven by the PWM controller.

11. The electronics assembly of claim 9, wherein the ZPD module comprises a first substrate and a second substrate, and the plurality of capacitors is disposed in a capacitor layer positioned between the first and second substrates.

12. The electronics assembly of claim 8, further comprising a first connection structure that electrically connects connection points of the ZPD module to corresponding connection points on the processor substrate.

13. The electronics assembly of claim 12, further comprising a second connection structure that electrically connects connection points on the processor substrate to corresponding connection points on the motherboard.

14. The electronics assembly of claim 13, wherein the first and second connection structures are different types.

15. The electronics assembly of claim 14, wherein the first connection structure comprises a land grid array (LGA), and the second connection structure comprises a ball grid array (BGA).

16. A z-axis power delivery (ZPD) module, comprising:
a first substrate and a second substrate;
a capacitor layer disposed between the first and second substrates, the capacitor layer comprising a plurality of capacitors and a controller;
a plurality of sub-modules mounted on the second substrate, each of the sub-modules comprising a pair of synchronous transistors driven by the controller; and
a connection structure disposed on the first substrate and is electrically connected to a processor substrate along a vertical axis.

17. The ZPD module of claim 16, wherein the controller comprises a pulse width modulation (PWM) controller.

18. The ZPD module of claim 16, wherein the capacitor layer further comprises signal connectors and power connectors that electrically connect the capacitors and the controller to the plurality of sub-modules.

19. The ZPD module of claim 16, wherein the capacitor layer is formed using an open frame, a molding compound, or embedded capacitors within the first substrate.

20. The ZPD module of claim 16, further comprising a cold plate that is thermally coupled to the plurality of sub-modules.
